(19) United States
(12) Patent Application Publication
(10) Pub. No.: US 2007/0007643 A1
(43) Pub. Date: Jan. 11, 2007

(54) SEMICONDUCTOR MULTI-CHIP PACKAGE

(75) Inventors: KWANG JAE OH, KYUNGKI-DO (KR); JE HONG SUNG, KYUNGKI-DO (KR); JIN WAUN KIM, KYUNGKI-DO (KR)

Correspondence Address: LOWE HAUPTMAN BERNER, LLP, 1700 DIAGONAL ROAD, SUITE 300, ALEXANDRIA, VA, 22314, US

(73) Assignee: SAMSUNG ELECTRO-MECHANICS CO., LTD., KYUNGKI-DO (KR)

(21) Appl. No.: 11/428,795

(22) Filed: Jul. 5, 2006

(30) Foreign Application Priority Data
Jul. 5, 2005 (KR) 10-2005-60380

(51) Int. Cl. H01L 23/12

(52) U.S. Cl. 257/701; 257/723

(57) ABSTRACT

The invention provides a semiconductor multi-chip package including a substrate, a first semiconductor chip mounted on the substrate and a second semiconductor chip disposed directly above the first semiconductor chip. The package further includes a spacer disposed between the substrate and the second semiconductor chip to maintain a vertical interval between the first and second semiconductor chips and electrically connect the second semiconductor chip to the substrate. The invention minimizes noise generated through a bonding wire connecting the substrate with the chip to ensure stable operation of the chip, and reduces the size of the substrate and the number of mounted components, thereby achieving miniaturization of the package.

### CLAIM OF PRIORITY

This application claims the benefit of Korean Patent Application No. 2005-60380 filed on Jul. 5, 2005, in the Korean Intellectual Property Office, the disclosure of which is incorporated herein by reference.

### BACKGROUND OF THE INVENTION

1. Field of the Invention

The present invention relates to a multi-chip package with at least two semiconductor chips packaged therein, and more particularly, to a semiconductor multi-chip package which is designed to minimize noise generated through a bonding wire connecting a substrate with a chip to ensure stable operation of the chip, and to reduce the size of a substrate and number of components mounted thereon, thereby achieving miniaturization.

2. Description of the Related Art

Electronic devices are becoming more miniaturized and multi-functional to meet the needs arising from recent developments in the semiconductor industry and the users. Multi-chip packaging technology, which is developed to meet such needs, packages a single type or different types of semiconductor chips in a single unit package.

This is more advantageous in terms of package size, weight or mounting area compared with packaging each semiconductor chip in one package. Thus, the multi-chip packaging technology is extensively applied to mobile phones and the like that require miniaturization and light weight in order to reduce mounting area and weight thereof.

In general, to package a plurality of semiconductor elements such as chips or dies in a single package, the semiconductor elements are either arranged in a stacked structure or aligned in parallel. In the case of the former, the stacked structure complicates the manufacturing process in a limited thickness. In the case of the latter, at least two semiconductor chips are disposed on the same plane, which renders it difficult to achieve miniaturization of the package.

In general, semiconductor chips are stacked in a package that needs to be miniaturized and light-weighted. Such an exemple of a conventional multi-chip package is described hereunder.

FIG. 1 is a sectional view illustrating the conventional multi-chip package. The multi-chip package 1 shown in FIG. 1 includes a first semiconductor chip 10 mounted on a substrate 2, a second semiconductor chip 20 disposed above the first semiconductor chip 10 in a predetermined interval and a spacer 30 having a predetermined height. The spacer 30 is disposed between the second semiconductor chip 20 and the substrate 2 to maintain a predetermined interval between the first and second semiconductor chips 10 and 20.

Each of the semiconductor chips 10 and 20 is adhered by a surface opposite of the active surface that has an integrated circuit formed thereon. The active surfaces of the semiconductor chips 10 and 20 face the same direction.

The first semiconductor chip 10 is electrically connected to the substrate 2 with chip pads thereof wire-bonded to bonding pads 43 of the substrate 2 by bonding wires 44. The second semiconductor chip 20 is electrically connected to the substrate 2 with chip pads thereof wire-bonded to bonding pads 41 of the substrate 2 by bonding wires 42.

In addition, plastic encapsulating material such as epoxy molding compound completes the package body in the upper part of the substrate 2 where at least one electric component is mounted by sealing the first and second semiconductor chips 10 and 20 and mounted components 15 to protect them from the external environment. Solder balls (not shown) may be provided on the lower surface of the substrate 2 as external terminals for electric connection to the outside.

In the meantime, a supplementary spacer 35 is disposed between the first and second semiconductor chips 10 and 20. The substrate 2 is a ceramic substrate manufactured in Low Temperature Co-fired Ceramic (LTCC) process to have passive elements such as a resistor, a capacitor and a coil embedded therein.

However, in such a configuration of the conventional multi-chip package 1, the second bonding wire 42 connecting the second semiconductor chip 20 and the substrate 2 is longer than the first bonding wire 44 electrically connecting the first semiconductor chip 10 and the substrate 2. This entails higher incidence of noise during transmission of signals and greater bonding inductance, and thus the operation is unstable.

In addition, as the second bonding wire 42 has an end connected to the second semiconductor chip 20 and the other end directly bonded to the substrate 2, a horizontal length L between the bonding locations of the second bonding wire 42 is longer, thus limiting reduction of the size of the substrate 2 for miniaturization.

### SUMMARY OF THE INVENTION

The present invention has been made to solve the foregoing problems of the prior art and therefore an object of certain embodiments of the present invention is to provide a semiconductor multi-chip package which can minimize noise generated through a bonding wire connecting a substrate with a chip and reduce the size of the substrate and number of components mounted thereon, thereby achieving miniaturization.

According to an aspect of the invention for realizing the object, there is provided a semiconductor multi-chip package including: a substrate; a first semiconductor chip mounted on an upper surface of the substrate; at least one second semiconductor chip disposed directly above the first semiconductor chip; and a spacer disposed between the substrate and the second semiconductor chip to maintain a predetermined interval between the first and second semiconductor chips and electrically connect the second semiconductor chip to the substrate.

Preferably, the first semiconductor chip is wire-bonded onto the substrate.

Preferably, the first semiconductor chip is flip-chip bonded onto the substrate.

Preferably, the second semiconductor chip is wire-bonded onto the spacer.

Preferably, the spacer comprises a Low Temperature Co-fired Ceramic (LTCC) substrate having at least one passive element therein.

Preferably, the spacer has a portion of an upper surface adhered to a lower surface of the second semiconductor chip with an adhesive, and has an undersurface adhered to the substrate via solder balls therebetween.

Preferably, the semiconductor multi-chip package according to the present invention further includes an encapsulant that covers the first and second semiconductor chips on the substrate.

Preferably, the semiconductor multi-chip package according to the present invention further includes a supplementary spacer between the first semiconductor chip and the second semiconductor chip, and preferably, the supplementary spacer is made of insulation material.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a sectional view illustrating a semiconductor multi-chip package according to prior art;

FIG. 2 is a sectional view illustrating a semiconductor multi-chip package according to the present invention; and

FIG. 3 is a plan view illustrating the semiconductor multi-chip package according to the present invention.

### DETAILED DESCRIPTION OF THE PREFERRED EMBODIMENT

Preferred embodiments of the present invention will now be described in detail with reference to the accompanying drawings.

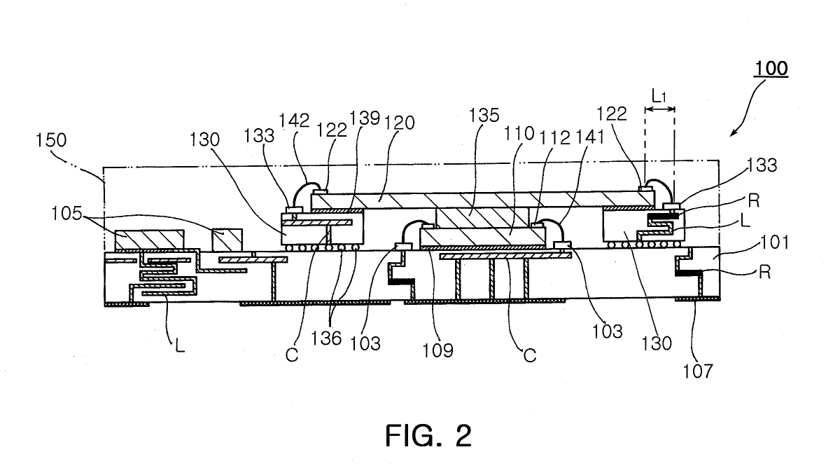

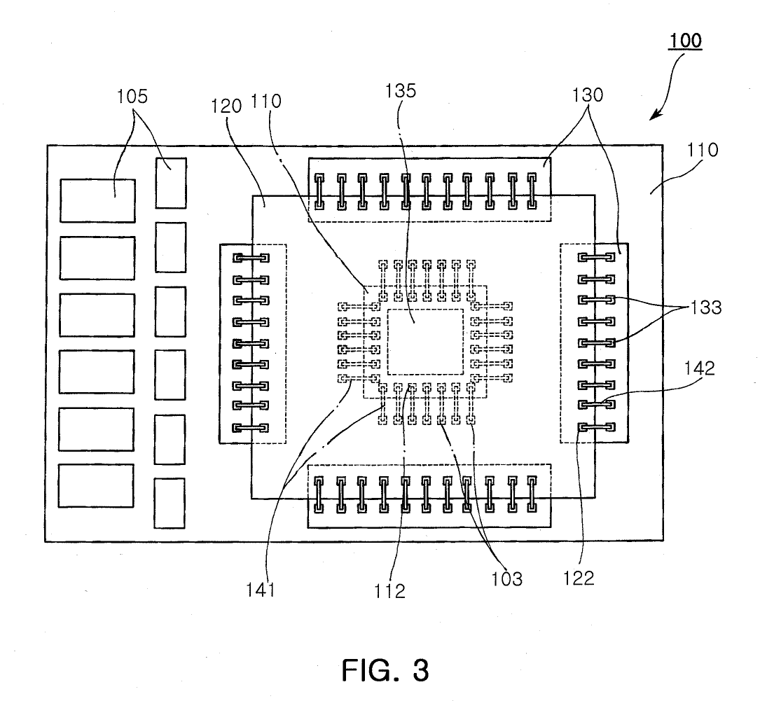

FIG. 2 is a sectional view illustrating a semiconductor multi-chip package according to the present invention, and FIG. 3 is a plan view illustrating the semiconductor multi-chip package according to the present invention.

As shown in FIGS. 2 and 3, according to a preferred embodiment of the present invention, the semiconductor multi-chip package 100 achieves miniaturization of a final product by reducing the number of components and the size of a substrate. The semiconductor multi-chip package 100 includes a substrate 101, first and second semiconductor chips 110 and 120 and a spacer 130.

That is, the substrate 101, which is a ceramic substrate with at least one ceramic layer stacked, has various circuits pattern-printed thereon, a plurality of bonding pads 103 for wire-bonding, and a plurality of components 105 mounted in accordance with the circuits on an upper surface thereof.

In addition, the substrate 101 has lower terminals 107 on an undersurface thereof and the lower terminals 107 have solder balls (not shown) for electrical connection with a main substrate. Thereby, the substrate 101 can be mounted on the main substrate with the solder balls (not shown) therebetween.

Herein, the substrate 101 is a Low Temperature Co-fired Ceramic (LTCC) substrate. The LTCC substrate is obtained by first, forming passive elements R, L and C (filter, balun and coupler) for configuring the circuits on a plurality of green sheets made of glass-ceramics, via screen printing and photo patterning using highly conductive Ag, Cu, etc. With these green sheets stacked on one another, ceramic and metal conductors are fired simultaneously at a temperature of 1000° C. or lower to obtain the LTCC substrate.

Thereby, the passive elements such as a capacitor, a resistor and an inductor are embedded in the substrate 101 in the form of patterns.

The first semiconductor chip 110 is a chip component which is mounted on an upper surface of the substrate 101 to be electrically connected to the circuits pattern-printed on an upper surface of the substrate 101. As shown in FIGS. 2 and 3, adhered to the substrate 101 by an adhesive 109, the first semiconductor chip 110 can be wire-bonded onto the substrate 101 by a plurality of first wires 141.

Each of the first bonding wires 141 is a conductive member having one end bonded to a chip pad 112 formed on an upper surface of the first semiconductor chip 110 and the other end bonded to the bonding pad 103 formed on the substrate 101.

However, the first semiconductor chip 110 is not limited to the above, and alternatively can be flip-chip bonded to an upper surface of the substrate 101, with ball pads (not shown) and a plurality of solder balls (not shown) formed on a lower surface thereof.

In addition, the second semiconductor chip 120 is composed of at least one chip component disposed directly above the first semiconductor chip 110 in a predetermined interval. The second semiconductor chip 120 is not directly connected to the substrate 101 but stacked in parallel and above the substrate 101 with a spacer 130 having conductive lines formed therein disposed therebetween.

The first and second semiconductor chips 110 and 120 may be ones selected from a group consisting of a memory chip such as SRAM and DRAM, a digital integrated circuit chip, an RF integrated circuit chip and a base band chip.

In addition, the spacer 130 has upper and lower ends thereof connected respectively to an upper surface of the substrate 101 and a lower surface of the second semiconductor chip 120, and having a thickness greater than the height of the first semiconductor chip 110 mounted on the substrate 101, in order to maintain a vertical interval between the first and second semiconductor chips 110 and 120.

Herein, the spacer 130 is composed of at least two LTCC substrates with at least one passive elements R, L and C (filter, balun and coupler) embedded therein, and disposed along the outer peripheral portions of the second semiconductor chip 120 to electrically connect the second semiconductor chip 120 with the substrate 101.

Thus, the passive elements such as a decoupling capacitor or Electrostatic Discharge (ESD) device that may be required depending on the operation of the second semiconductor chip 120 can be embedded in the spacer 130 without being mounted on the substrate 101, thereby reducing the number of components mounted on the substrate 101.

The second semiconductor chip 120 is bonded to the spacer 140 by second bonding wires 142. Each of the second bonding wires 142 has an end bonded to a chip pad 122 formed on an upper surface of the second semiconductor chip 120 and the other end bonded to a bonding pad 133 formed on an upper surface of the spacer 130. The bonding pads 133 are electrically connected to the passive elements R, L and C (filter, balun and coupler) through vias or patterns.

Here, the spacer 130 is fixedly adhered to a lower surface of the second semiconductor chip 120 with an insulating adhesive 139.

The spacer 130 has a plurality of solder pads on a lower surface thereof to be electrically connected to the pattern circuits formed on the substrate 101 via solder balls 136.

Thereby, the second semiconductor chip 120 is electrically connected to the substrate 101 by the second bonding wires 142 and the solder balls 136.

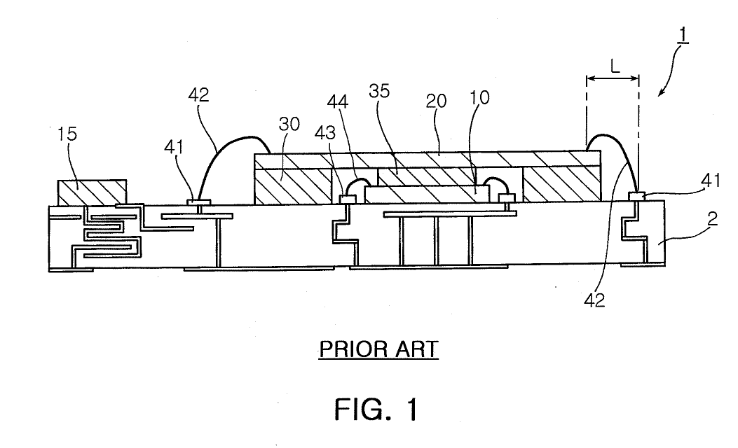

Further, a horizontal length L1 measured between the chip pad 122 and the bonding pad 133 connected, respectively, to each end of the second bonding wire 142 is shorter than a horizontal length L (see FIG. 1) measured between the chip pad and the bonding pad 41 of the substrate 2 connected, respectively, to each end of the second bonding wire 42 in the conventional package. Thus, the second bonding wire 142 can be formed in a shorter length, and also the substrate 101 where the first and second semiconductor chips 110 and 120 are mounted can be designed smaller.

As the second bonding wires 142 are formed in a shorter length, noise of signals transmitted therethrough can be reduced, thereby minimizing occurrence of parasitic component due to bonding inductance.

In the meantime, an encapsulant 150 made of plastic encapsulating material such as epoxy molding compound is formed on the substrate 101 to protect the mounted components 105, the first and second semiconductor chips 110 and 120 and the first and second bonding wires 141 and 142 from being damaged or corroded by the outside environment, thereby completing the package.

In addition, a supplementary spacer 135 made of insulation material such as silicone can be additionally disposed between the first semiconductor chip 110 mounted on the substrate 101 and the second semiconductor chip 120 adhered to the spacer 130, thereby stably maintaining an interval between the first and second semiconductor chips 110 and 120.

Herein, it is preferable that the supplementary spacer 135 is formed in a shape substantially the same as those of the first and second semiconductor chips 110 and 120, and formed smaller than an upper surface area of the first semiconductor chip 110.

According to a preferred embodiment of the invention as set forth above, the passive elements involved in the operation of the second semiconductor chip can be embedded in the LTCC spacer disposed between the first and second semiconductor chips instead of being mounted on the substrate. This allows reducing the number of components mounted on the substrate and the size of the substrate, thereby miniaturizing the final product.

Further, the second bonding wires can be formed in a length smaller than that in the prior art, thus reducing noise of a signal transmitted therethrough and occurrence of parasitic component due to bonding inductance. Thereby, the stable operation of the package is ensured to enhance reliability of the package and attain stable electric characteristics.

While the present invention has been shown and described in connection with the preferred embodiments, it will be apparent to those skilled in the art that modifications and variations can be made without departing from the spirit and scope of the invention as defined by the appended claims.

What is claimed is:

1. A semiconductor multi-chip package comprising:
a substrate;
a first semiconductor chip mounted on an upper surface of the substrate;
at least one second semiconductor chip disposed directly above the first semiconductor chip; and
a spacer disposed between the substrate and the second semiconductor chip to maintain a predetermined interval between the first and second semiconductor chips and electrically connect the second semiconductor chip to the substrate.

2. The semiconductor multi-chip package according to claim 1, wherein the first semiconductor chip is wire-bonded onto the substrate.

3. The semiconductor multi-chip package according to claim 1, wherein the first semiconductor chip is flip-chip bonded onto the substrate.

4. The semiconductor multi-chip package according to claim 1, wherein the second semiconductor chip is wire-bonded onto the spacer.

5. The semiconductor multi-chip package according to claim 1, wherein the spacer comprises a Low Temperature Co-fired Ceramic (LTCC) substrate having at least one passive element therein.

6. The semiconductor multi-chip package according to claim 1, wherein the spacer has a portion of an upper surface adhered to a lower surface of the second semiconductor chip with an adhesive, and has an undersurface adhered to the substrate via solder balls therebetween.

7. The semiconductor multi-chip package according to claim 1, further comprising an encapsulant that covers the first and second semiconductor chips on the substrate.

8. The semiconductor multi-chip package according to claim 1, further comprising a supplementary spacer between the first semiconductor chip and the second semiconductor chip.

9. The semiconductor multi-chip package according to claim 1, wherein the supplementary spacer is made of insulation material.
